(19) United States
(12) Patent Application Publication
(10) Pub. No.: US 2025/0010421 A1
(43) Pub. Date: Jan. 9, 2025

(54) SUBSTRATE PROCESSING METHOD AND SUBSTRATE PROCESSING APPARATUS

(71) Applicant: EBARA CORPORATION, Tokyo (JP)

(72) Inventor: Masayuki NAKANISHI, Tokyo (JP)

(21) Appl. No.: 18/710,140

(22) PCT Filed: Oct. 21, 2022
(86) PCT No.: PCT/JP2022/039327

§ 371 Date: May 14, 2024

(30) Foreign Application Priority Data
Nov. 18, 2021 (JP) 2021-187594

(51) Int. Cl. B24B 9/02; B24B 37/11

(52) U.S. Cl. CPC B24B 9/02; B24B 37/11

(57) ABSTRACT

The present invention relates to a substrate processing apparatus for processing a substrate, such as a wafer, and more particularly to a substrate processing method and a substrate processing apparatus for polishing a bevel portion of the substrate and performing CMP processing of a flat portion of the substrate. The substrate processing method includes: polishing a bevel portion (B) of each of the plurality of substrates (W) by a polishing tool such that slope surfaces(S) of bevel portions (B) of the plurality of substrates (W) have the same slope angles (α); and performing CMP processing of a flat portion (P) of each of the plurality of substrates (W) whose bevel portions (B) have been polished.

### TECHNICAL FIELD

The present invention relates to a substrate processing apparatus for processing a substrate, such as a wafer, and more particularly to a substrate processing method and a substrate processing apparatus for polishing a bevel portion of the substrate and performing CMP processing of a flat portion of the substrate.

### BACKGROUND ART

Chemical mechanical polishing (CMP) has been known as a technique for use in a manufacturing process of semiconductor devices. A CMP apparatus for performing CMP processing is configured to hold and rotate a substrate with a CMP head, and then press the substrate against a polishing pad on a rotating polishing table to perform CMP processing of a surface of the substrate (more specifically, a flat portion of the substrate). During polishing of the substrate, a polishing liquid (e.g., slurry) is supplied onto the polishing pad. The flat portion of the substrate is planarized by a combination of a chemical action of the polishing liquid and mechanical action(s) of abrasive grains contained in the polishing liquid and/or the polishing pad.

### CITATION LIST

### Patent Literature

Patent document 1: Japanese laid-open patent publication No. 2010-50436

### SUMMARY OF INVENTION

### Technical Problem

Even if substrates are bare wafers with the same specifications, a shape of a bevel portion of each substrate may vary. Furthermore, conditions of film-formation of a dielectric film, a metal film, etc., on the substrates may vary. Therefore, the shapes of the bevel portions of the substrates before CMP processing vary from substrate to substrate. When CMP processing is performed on a plurality of substrates, polishing rates of the substrates may be affected by variation in the shape of the bevel portion of each substrate. Therefore, in order to perform CMP processing of the flat portions of the substrates to achieve an uniform polishing profile, it has been necessary to adjust CMP-processing conditions for each substrate depending on the shape of the bevel portion of each substrate.

Therefore, the present invention provides a substrate processing method and a substrate processing apparatus capable of efficiently performing CMP processing of flat portions of a plurality of substrates without adjusting CMP-processing conditions according to a shape of a bevel portion of each substrate.

### Solution to Problem

FIG. 1 is an enlarged cross-sectional view showing a periphery of a substrate W when CMP processing is being performed on the substrate W. The substrate W is rotated by a CMP head (not shown). During the CMP processing, a flat portion P of the substrate W is pressed against a polishing surface 72a of a polishing pad 72 on a rotating polishing table (not shown). The inventor has found that a manner in which the polishing pad 72 deforms when the substrate W is being pressed against the polishing pad 72 differs depending on a shape of a bevel portion B of the substrate W. As shown in FIG. 1, when the substrate W is pressed against the polishing surface 72a of the polishing pad 72, the polishing pad 72 deforms along a slope surface S of the bevel portion B of the substrate W. Such deformation of the polishing pad 72 may affect a polishing rate of the flat portion P of the substrate W, in particular a polishing rate of an edge portion of the substrate W.

Thus, in an embodiment, there is provided a substrate processing method of processing a plurality of substrates, comprising: polishing a bevel portion of each of the plurality of substrates by a polishing tool such that slope surfaces of bevel portions of the plurality of substrates have the same slope angles; and performing CMP processing of a flat portion of each of the plurality of substrates whose bevel portions have been polished.

In an embodiment, polishing of the bevel portion of each of the plurality of substrates comprises pressing the polishing tool against a slope surface of the bevel portion each of the plurality of substrates with the same angle of inclination of the polishing tool with respect to the flat portions of the plurality of substrates while each substrate is being rotated.

In an embodiment, the substrate processing method further comprises: measuring a shape of a bevel portion of at least one of the plurality of substrates before polishing of the bevel portions of the plurality of substrates.

In an embodiment, the substrate processing method further comprises: determining a polishing condition for the bevel portions of the plurality of substrates based on a measurement result of the shape of the bevel portion.

In an embodiment, the substrate processing method further comprises: measuring of a shape of a bevel portion of at least one of the plurality of substrates after polishing of the bevel portions of the plurality of substrates; and polishing the bevel portion of the at least one substrate again when a slope angle of the bevel portion of the at least one substrate has not reached a predetermined angle.

In an embodiment, a bevel-portion polishing module configured to polish the bevel portions, and a CMP module configured to perform the CMP processing are arranged in the same housing, and polishing of the bevel portion of each substrate and the CMP processing of each substrate are performed successively.

In an embodiment, there is provided a substrate processing apparatus for processing a plurality of substrates, comprising: a bevel-portion polishing module configured to press a polishing tool against a bevel portion of each of the plurality of substrates to polish the bevel portion; and a CMP module configured to perform CMP processing of a flat portion of each of the plurality of substrates whose bevel portions have been polished, wherein the bevel-portion polishing module is configured to polish the bevel portions of the plurality of substrates such that slope surfaces of the bevel portions of the plurality of substrates have the same slope angles.

In an embodiment, the bevel-portion polishing module includes a substrate holder configured to hold and rotate each of the plurality of substrates, and the bevel-portion polishing module is configured to press the polishing tool against a slope surface of the bevel portion of each of the plurality of substrates with the same angle of inclination of the polishing tool with respect to the flat portions of the plurality of substrates while each substrate is being rotated by the substrate holder.

In an embodiment, the substrate processing apparatus further comprises: a bevel-portion-shape measuring module configured to measure a shape of a bevel portion of at least one of the plurality of substrates.

In an embodiment, the substrate processing apparatus further comprises: an operation controller configured to control operations of the bevel-portion-shape measuring module and the bevel-portion polishing module, the operation controller being configured to determine a polishing condition for the bevel portions of the plurality of substrates based on a measurement result of the shape of the bevel portion.

In an embodiment, the bevel-portion-shape measuring module is configured to measure a shape of a bevel portion of at least one of the plurality of substrates after polishing of the bevel portions of the plurality of substrates, and the bevel-portion polishing module is configured to polish the bevel portion of the at least one substrate again when a slope angle of the bevel portion of the at least one substrate has not reached a predetermined angle.

In an embodiment, the bevel-portion polishing module and the CMP module are arranged in the same housing, and polishing of the bevel portion of each substrate by the bevel-portion polishing module and the CMP processing of each substrate by the CMP module are performed successively.

### Advantageous Effects of Invention

According to the present invention, the bevel portions of the plurality of substrates are polished until the bevel portions have the same slope angles, and CMP processing is performed on the flat portions of the plurality of substrates whose bevel portions have been polished. As a result, CMP processing of the flat portion of the substrate can be efficiently performed to achieve the same polishing profile of the flat portions of the plurality of substrates (in particular, edge portions of the substrates).

### BRIEF DESCRIPTION OF DRAWINGS

FIG. 1 is an enlarged cross-sectional view showing a periphery of a substrate when CMP processing is being performed on the substrate;

FIG. 2A is an enlarged cross-sectional view showing a periphery of a substrate;

FIG. 2B is an enlarged cross-sectional view showing a periphery of a substrate;

FIG. 3 is a plan view showing an embodiment of a substrate processing apparatus;

FIG. 4A is a schematic diagram showing an embodiment of a bevel-portion-shape measuring module;

FIG. 4B is a schematic diagram showing an embodiment of the bevel-portion-shape measuring module;

FIG. 5 is an enlarged cross-sectional view showing bevel portions of substrates before and after polishing of the substrates by bevel-portion polishing module;

FIG. 6 is a schematic diagram showing an embodiment of the bevel-portion polishing module;

FIG. 7 is a plan view showing a tilting mechanism configured to tilt a polishing head to a predetermined angle;

FIG. 8 is a perspective view showing an embodiment of a CMP module;

FIG. 9 is a plan view showing a configuration of an interior of a first housing according to another embodiment of the substrate processing apparatus; and

FIG. 10 is a plan view showing a configuration of an interior of a second housing according to another embodiment of the substrate processing apparatus.

### DESCRIPTION OF EMBODIMENTS

Hereinafter, embodiments of the present invention will be described with reference to the drawings.

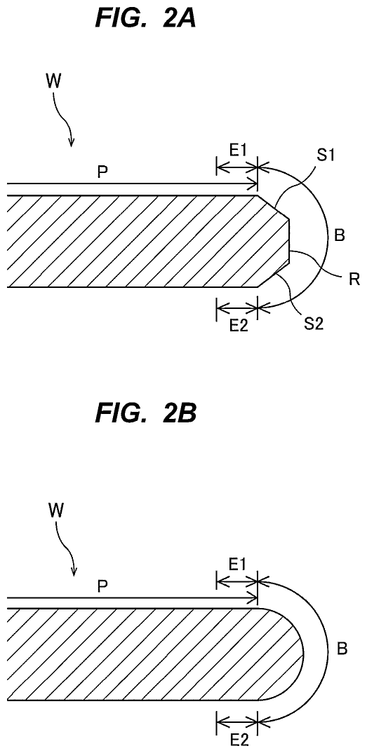

FIGS. 2A and 2B are enlarged cross-sectional views each showing a periphery of a substrate W. More specifically, FIG. 2A is a cross-sectional view of a substrate W of a so-called straight type, and FIG. 2B is a cross-sectional view of a substrate W of a so-called round type. A bevel portion B is a portion constituting an outermost circumferential surface inclined with respect to a flat portion P of the substrate W and has a beveled shape or a rounded shape. The flat portion P of the substrate W is a surface on which chemical mechanical polishing (CMP) processing to be performed, which will be described later, and is typically a device surface on which devices are formed.

In the substrate W of FIG. 2A, the bevel portion B is an outermost peripheral surface constituting an upper slope surface (or an upper bevel portion) S1, a lower slope surface (or a lower bevel portion) S2, and a side portion (or an apex) R of the substrate W. In the substrate W of FIG. 2B, the bevel portion B is a portion constituting an outermost peripheral surface of the substrate W and has a curved cross section. A top-edge portion E1 is an annular flat portion located radially inwardly of the bevel portion B and located in the device surface of the substrate W. A bottom-edge portion E2 is an annular flat portion located at an opposite side from the top-edge portion E1 and located radially inwardly of the bevel portion B. The top-edge portion E1 may include a region in which devices are formed. In this specification, a region described as the bevel portion B may be a region including the top-edge portion E1 and the bottom-edge portion E2.

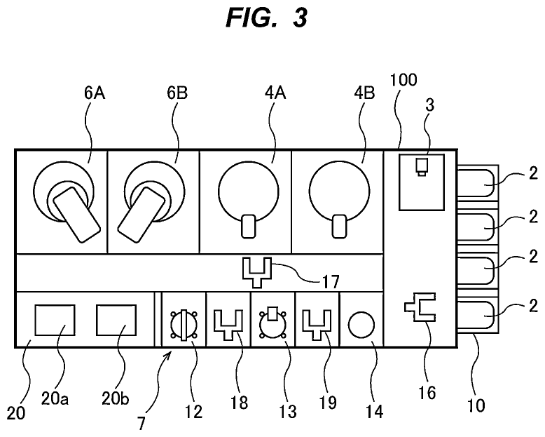

FIG. 3 is a plan view showing an embodiment of a substrate processing apparatus. The substrate processing apparatus includes a bevel-portion-shape measuring module 3, bevel-portion polishing modules 4A and 4B, CMP modules 6A and 6B, a cleaning-drying section 7, a load port 10, a first transfer robot 16, a second transfer robot 17, a third transfer robot 18, and a fourth transfer robot 19. The bevel-portion-shape measuring module 3, the bevel-portion polishing modules 4A and 4B, the CMP modules 6A and 6B, the cleaning-drying section 7, the first transfer robot 16, the second transfer robot 17, the third transfer robot 18, and the fourth transfer robot 19 are arranged in the same housing 100. In one embodiment, the bevel-portion-shape measuring module 3 may be arranged outside the housing 100.

A plurality of substrates to be processed are housed in a substrate cassette 2, and the substrate cassette 2 is placed on the load port 10. The first transfer robot 16 is arranged adjacent to the load port 10. The first transfer robot 16 removes a substrate to be processed from the substrate cassette 2 on the load port 10, and transports the substrate to the bevel-portion-shape measuring module 3. The first transfer robot 16 transports the substrate whose shape of the bevel portion has been measured by the bevel-portion-shape measuring module 3 from the bevel-portion-shape measuring module 3 to the second transfer robot 17. The first transfer robot 16 may remove the substrate to be processed from the substrate cassette 2 on the load port 10, and may transport the substrate to the second transfer robot 17 without transporting to the bevel-portion-shape measuring module 3.

In this embodiment, the substrate processing apparatus includes two bevel-portion polishing modules 4A and 4B and two CMP modules 6A and 6B, while in one embodiment, the substrate processing apparatus may include one bevel-portion polishing module and one CMP module, or may include three or more bevel-portion polishing modules and three or more CMP modules.

The bevel-portion polishing modules 4A and 4B, and the CMP modules 6A and 6B are arranged along a longitudinal direction of the housing 100. The bevel portion of the substrate to be processed is polished by at least one of the bevel-portion polishing modules 4A and 4B, and CMP processing is then performed on the flat portion of the substrate by at least one of the CMP modules 6A and 6B. The bevel portion may be polished by either the bevel-portion polishing module 4A or 4B, or the bevel portion may be polished in two stages by the two bevel-portion polishing modules 4A and 4B. CMP processing may be performed by either the CMP module 6A or 6B, or CMP processing may be performed in two stages by the two CMP modules 6A and 6B.

The second transfer robot 17 is arranged adjacent to the bevel-portion polishing modules 4A and 4B, the CMP modules 6A and 6B, and the cleaning-drying section 7. The second transfer robot 17 is configured to receive the substrate from the first transfer robot 16, and transport the substrate between the bevel-portion polishing modules 4A, 4B and the CMP modules 6A, 6B. Further, the second transfer robot 17 is configured to transport the substrate received from any one of the CMP modules 6A and 6B to the cleaning-drying section 7.

The cleaning-drying section 7 includes a first cleaning module 12 and a second cleaning module 13 configured to clean the substrate whose flat portion has been chemically mechanically polished by any one of the CMP modules 6A and 6B, and a drying module 14 configured to dry the cleaned substrate. The first cleaning module 12, the second cleaning module 13, and the drying module 14 are arranged along the longitudinal direction of the housing 100. The first cleaning module 12 is configured to perform scrub cleaning with use of a roll-shaped sponge member. The second cleaning module 13 is configured to perform scrub cleaning with use of a pencil-shaped sponge member. In this embodiment, the cleaning-drying section 7 includes the first cleaning module 12 and the second cleaning module 13, while in one embodiment, the cleaning-drying section 7 may include either the first cleaning module 12 or the second cleaning module 13.

The third transfer robot 18 is disposed between the first cleaning module 12 and the second cleaning module 13. The fourth transfer robot 19 is disposed between the second cleaning module 13 and the drying module 14. The third transfer robot 18 is configured to transport the substrate between the first cleaning module 12 and the second cleaning module 13. The fourth transfer robot 19 is configured to transport the substrate between the second cleaning module 13 and the drying module 14.

The substrate processing apparatus processes a plurality of substrates by sequentially performing polishing of the bevel portion by the bevel-portion polishing module 4A and/or 4B, CMP processing of the flat portion by the CMP module 6A and/or 6B, and cleaning and drying of the substrate by the cleaning-drying section 7 for each of the plurality of substrates.

The substrate processing apparatus further includes an operation controller 20 electrically coupled to the bevel-portion-shape measuring module 3, the bevel-portion polishing modules 4A and 4B, the CMP modules 6A and 6B, the cleaning-drying section 7, the first transfer robot 16, the second transfer robot 17, the third transfer robot 18, and the fourth transfer robot 19. The operation controller 20 is configured to control operations of the bevel-portion-shape measuring module 3, the bevel-portion polishing modules 4A and 4B, the CMP modules 6A and 6B, the cleaning-drying section 7, the first transfer robot 16, the second transfer robot 17, the third transfer robot 18, and the fourth transfer robot 19.

The operation controller 20 includes at least one computer. The operation controller 20 includes a memory 20a, and an arithmetic device 20b. The arithmetic device 20b includes a CPU (central processing unit), a GPU (graphic processing module), or the like configured to perform arithmetic operations according to instructions contained in programs stored in the memory 20a. The memory 20a includes a main memory (e.g., a random-access memory) to which the arithmetic device 20b is accessible, and an auxiliary memory (e.g., a hard disk drive or a solid state drive) configured to store data and the programs. However, the specific configuration of the operation controller 20 is not limited to these examples.

In the substrate processing apparatus of this embodiment, the bevel-portion polishing modules 4A and 4B, and the CMP modules 6A and 6B are arranged in the same housing 100. If the bevel-portion polishing modules 4A and 4B, and the CMP modules 6A and 6B are arranged in separate housings, it is necessary to clean and dry the substrate before moving the substrate between the housings. According to this embodiment, after the bevel portion is polished by the bevel-portion polishing module 4A and/or 4B, CMP processing can be sequentially performed by the CMP module 6A and/or 6B without cleaning and drying the substrate. Furthermore, a footprint can be made smaller compared to a case where the bevel-portion polishing modules 4A and 4B, and the CMP modules 6A and 6B are arranged in separate housings.

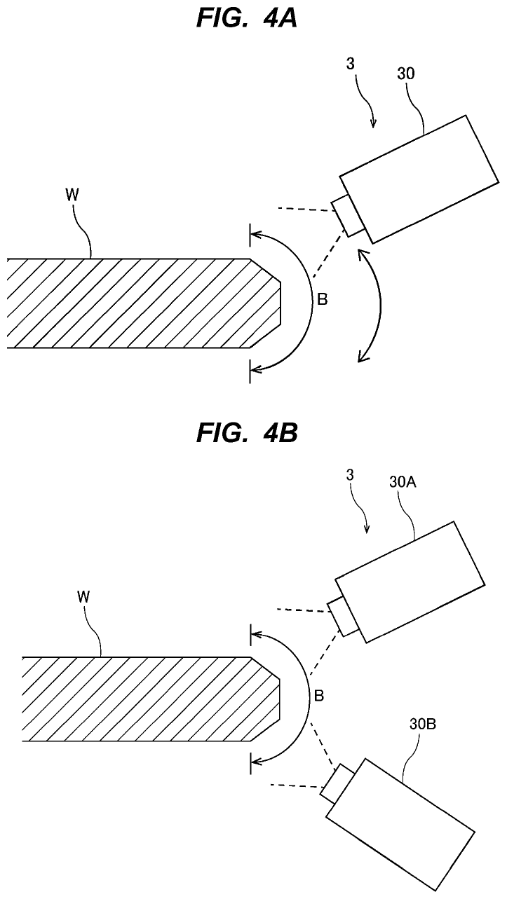

Next, details of a configuration of the bevel-portion-shape measuring module 3 will be described. FIGS. 4A and 4B are schematic diagrams each showing an embodiment of the bevel-portion-shape measuring module 3. As shown in FIG. 4A, the bevel-portion-shape measuring module 3 includes a shape measuring device 30 configured to measure a shape of the bevel portion B of the substrate W. The shape measuring device 30 is configured to measure a shape (including dimensions) of a measurement target by directing laser light to the measurement target and detecting laser light reflected from the measurement target. The shape measuring device 30 measures the shape of the bevel portion B of the substrate W by scanning the bevel portion B of the substrate W with the laser light.

In one embodiment, as shown in FIG. 4B, the bevel-portion-shape measuring module 3 may include two shape measuring devices 30A and 30B disposed at an upper side and a lower side of the bevel portion B of the substrate W. The bevel-portion-shape measuring module 3 may merge a measurement result of an upper part of the bevel portion B obtained by the shape measuring device 30A and a measurement result of a lower part of the bevel portion B obtained by the shape measuring device 30B to measure a shape of the entire bevel portion B.

The bevel-portion polishing modules 4A and 4B, details of which will be described later, are configured to polish a slope surface of the bevel portion B of the substrate W adjacent to the flat portion P on which CMP processing is to be performed by the CMP modules 6A and 6B. In the straight-type substrate shown in FIG. 2A, the slope surface to be polished by the bevel-portion polishing module 4A, 4B includes the upper slope surface S1. In the round-type substrate shown in FIG. 2B, the slope surface to be polished by the bevel-portion polishing module 4A, 4B is adjacent to the flat portion P and is inclined with respect to the flat portion P.

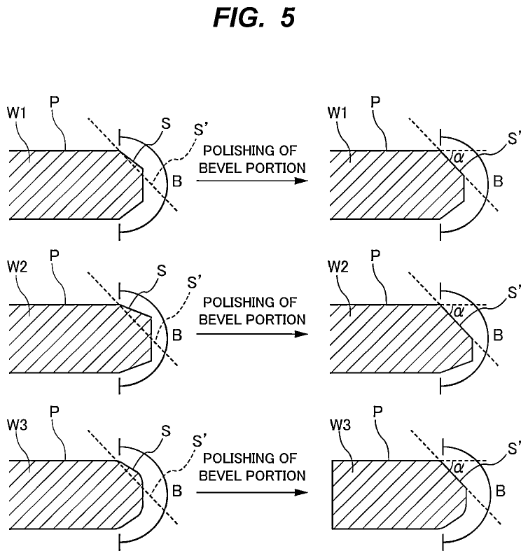

FIG. 5 is an enlarged cross-sectional view showing bevel portions of substrates before and after polishing of the substrates by the bevel-portion polishing module 4A and/or 4B. Three substrates W1, W2, and W3 before being polished by the bevel-portion polishing module 4A or 4B have bevel portions B of different shapes. More specifically, the three substrates W1, W2, and W3 have slope surfaces S of the bevel portions B having different slope angles. The bevel-portion polishing module 4A or 4B polishes the bevel portion B of each of the substrates W1, W2, and W3 such that the slope surfaces S of the substrates W1, W2, and W3 have the same slope angles. In FIG. 5, slope surfaces S′ of the substrates W1, W2, and W3 after being polished are represented by dashed lines. The slope surfaces S′ of the substrates W1, W2, and W3 after being polished are inclined at the same slope angle α with respect to the flat portions P of the substrates W1, W2, and W3.

The operation controller 20 determines polishing conditions of the bevel-portion polishing modules 4A and 4B for bevel portion B based on a measurement result of the shape of the bevel portion B of the substrate W measured by the bevel-portion-shape measuring module 3. The polishing conditions include, for example, a polishing time, a pressing force of a polishing tool against the substrate, and a rotation speed of the substrate. Measuring of the bevel portion B by the bevel-portion-shape measuring module 3 may be performed for all substrates, or may be performed only for a first substrate in the same processing lot as long as the polishing conditions can be determined.

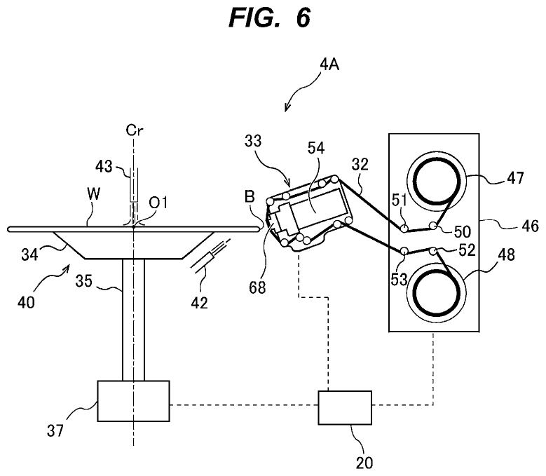

Next, details of configurations of the bevel-portion polishing modules 4A and 4B will be described. Since the bevel-portion polishing modules 4A and 4B have basically the same configuration, the bevel-portion polishing module 4A will be described below. FIG. 6 is a schematic diagram showing an embodiment of the bevel-portion polishing module 4A. In this embodiment, the bevel-portion polishing module 4A is configured to polish the bevel portion B of the substrate W by pressing a polishing tape 32 as a polishing tool against the bevel portion B of the substrate W with a polishing head 33. In one embodiment, the bevel-portion polishing module 4A may be configured to polish the bevel portion B using a whetstone as the polishing tool instead of the polishing tape 32, or may be configured to perform polishing (CMP processing) of the bevel portion B using a polishing pad (e.g., nonwoven fabric) as the polishing tool in the presence of a polishing liquid (e.g., slurry).

The bevel-portion polishing module 4A includes a substrate holder 40 configured to hold and rotate the substrate W to be polished, the polishing head 33 configured to press the polishing tape 32 against the bevel portion B of the substrate W, which is rotated by the substrate holder 40, to polish the bevel portion B of the substrate W, a lower supply nozzle 42 configured to supply liquid onto a lower surface of the substrate W, and an upper supply nozzle 43 configured to supply liquid onto an upper surface of the substrate W. An example of the liquid supplied to the substrate W is pure water. During polishing of the substrate W, the liquid is supplied from the lower supply nozzle 42 onto the lower surface of the substrate W, and the liquid is supplied from the upper supply nozzle 43 onto the upper surface of the substrate W.

FIG. 6 shows the substrate holder 40 when holding the substrate W. The polishing head 33 is oriented toward the bevel portion B of the substrate W when the substrate W is held by the substrate holder 40. The substrate holder 40 includes a holding stage 34 configured to hold the substrate W by vacuum suction, a shaft 35 coupled to a center portion of the holding stage 34, and a holding-stage driving mechanism 37 configured to rotate and vertically move the holding stage 34. The holding-stage driving mechanism 37 is configured to rotate the holding stage 34 about its own axis Cr, and is configured to be movable in a vertical direction along the axis Cr.

The substrate W is placed on a substrate holding surface of the holding stage 34 by the second transfer robot 17 (see FIG. 3) such that the center O1 of the substrate W is located on the axis Cr of the holding stage 34. The substrate W is held on the substrate holding surface of the holding stage 34 with the device surface (the flat portion P in FIG. 5) facing upward. The substrate holder 40 can rotate the substrate W about the axis Cr of the holding stage 34 (i.e., an axis of the substrate W), and can vertically move the substrate W along the axis Cr of the holding stage 34.

The bevel-portion polishing module 4A further includes a polishing-tape feeding mechanism 46 configured to feed the polishing tape 32 to the polishing head 33 and collect the polishing tape 32 from the polishing head 33. The polishing-tape feeding mechanism 46 includes a tape feeding reel 47 configured to feed the polishing tape 32 to the polishing head 33, and a tape take-up reel 48 configured to collect the polishing tape 32 that has been used in polishing of the substrate W. Not-shown tension motors are coupled to the tape feeding reel 47 and the tape take-up reel 48, respectively. The tension motors are configured to apply predetermined torque(s) to the tape feeding reel 47 and the tape take-up reel 48, so that a predetermined tension can be applied to the polishing tape 32.

The polishing tape 32 is fed to the polishing head 33 such that a polishing surface of the polishing tape 32 faces the bevel portion B of the substrate W. The polishing tape 32 is fed to the polishing head 33 from the tape feeding reel 47, and the used polishing tape 32 is collected by the tape take-up reel 48. The polishing-tape feeding mechanism 46 further includes a plurality of guide rollers 50, 51, 52, and 53 configured to support the polishing tape 32. An advancing direction of the polishing tape 32 is guided by the guide rollers 50, 51, 52, and 53.

The polishing head 33 includes a pressing member 68 configured to press the polishing surface of the polishing tape 32 against the substrate W, and an air cylinder (i.e., an actuator) 54 configured to move the pressing member 68 toward the bevel portion B of the substrate W. A pressing force on the polishing tape 32 against the substrate W is regulated by controlling a pressure of air supplied to the air cylinder 54. The pressing member 68 is arranged at a back side of the polishing tape 32 (at a back side from the polishing surface having abrasive grains).

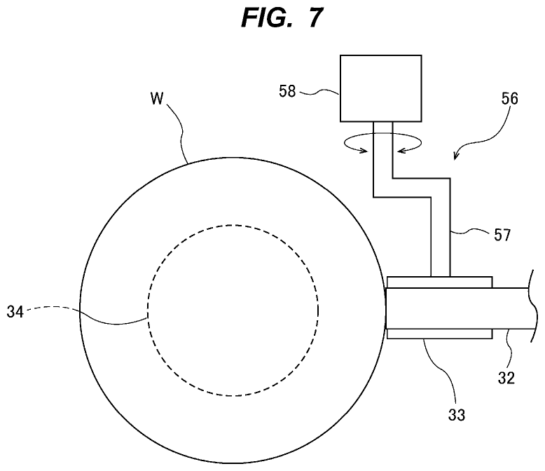

The bevel-portion polishing module 4A further includes a tilting mechanism 56 shown in FIG. 7. FIG. 7 is a plan view showing an embodiment of the tilting mechanism 56. As shown in FIG. 7, the tilting mechanism 56 is configured to tilt the polishing head 33 with respect to the substrate holding surface of the holding stage 34. More specifically, the tilting mechanism 56 includes a crank arm 57 coupled to the polishing head 33, and an arm rotating device 58 configured to rotate the crank arm 57. One end of the crank arm 57 is located at substantially the same height as that of the substrate holding surface of the holding stage 34, and is coupled to the arm rotating device 58. The other end of the crank arm 57 is coupled to the polishing head 33.

When the arm rotating device 58 rotates the crank arm 57, the entire polishing head 33 can be tilted with respect to the substrate W on the substrate holding surface of the holding stage 34. Further, the tilting mechanism 56 is configured to maintain a predetermined angle of inclination of the polishing head 33. Therefore, the polishing head 33 can polish the bevel portion B of the substrate W with the predetermined angle of inclination maintained. The specific configuration of the tilting mechanism 56 is not limited to the embodiment shown in FIG. 7 as long as the polishing head 33 can be tilted with respect to the substrate holding surface of the holding stage 34 and the substrate W.

The bevel-portion polishing module 4A is electrically coupled to the operation controller 20 configured to control operations of each component of the bevel-portion polishing module 4A. The polishing head 33, the substrate holder 40, the lower supply nozzle 42, the upper supply nozzle 43, the polishing-tape feeding mechanism 46, and the tilting mechanism 56 are electrically coupled to the operation controller 20. Operations of the polishing head 33, the substrate holder 40, the lower supply nozzle 42, the upper supply nozzle 43, the polishing-tape feeding mechanism 46, and the tilting mechanism 56 are controlled by the operation controller 20.

Polishing of the bevel portion B of the substrate W is performed with the polishing head 33 tilted at a predetermined angle by the tilting mechanism 56 while the angle of inclination of the polishing head 33 is maintained. The pressing member 68 is moved toward the substrate W by the air cylinder 54 to thereby press the polishing tape 32 against the bevel portion B of the substrate W from the back side of the polishing tape 32. In this manner, the polishing head 33 polishes the bevel portion B of the substrate W.

As described above, the bevel-portion polishing module 4A polishes the bevel portion of the substrate W under the polishing conditions determined based on the measurement result of the shape of the bevel portion B of the substrate W measured by the bevel-portion-shape measuring module 3. As described with reference to FIG. 5, the bevel-portion polishing modules 4A and 4B polish the bevel portions B such that the slope surfaces S of the bevel portions B of the plurality of substrates have the same slope angle α. More specifically, the polishing tape 32 is pressed against the slope surface S of the bevel portion B of each of the plurality of substrates with the same slope angle of the polishing tape 32 and the same angle of inclination of the pressing member 68 with respect to the flat portions P of the plurality of substrates, while each suberate is being rotated.

In one embodiment, a shape of the bevel portion B may be measured by the bevel-portion-shape measuring module 3 after polishing of the bevel portion B of the substrate by the bevel-portion polishing module 4A or 4B. When the slope angle of the slope surface S of the bevel portion B of the substrate has not reached the predetermined angle α, the bevel portion B may be polished again by the bevel-portion polishing module 4A or 4B. Measuring of the shape of the bevel portion B that has been polished may be performed for all of the plurality of substrates, or may be performed, for example, for one substrate of the plurality of substrates in the same processing lot.

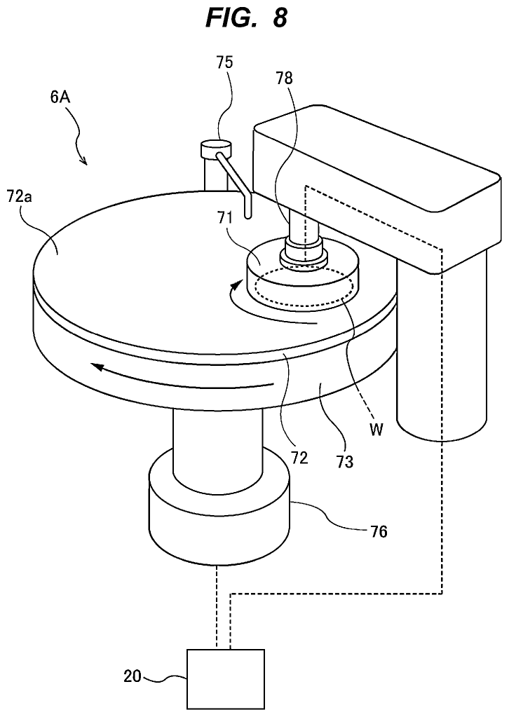

Next, details of configurations of the CMP modules 6A and 6B will be described. Since the CMP modules 6A and 6B have basically the same configuration, the CMP module 6A will be described below. FIG. 8 is a perspective view showing an embodiment of the CMP module 6A. The CMP module 6A includes a polishing table 73 configured to support a polishing pad 72, a CMP head 71 configured to press the substrate W having the flat portion against the polishing pad 72 to perform CMP processing, a table motor 76 configured to rotate the polishing table 73, and a polishing-liquid supply nozzle 75 configured to supply a polishing liquid, such as slurry, onto the polishing pad 72. The polishing pad 72 has an upper surface constituting a polishing surface 72a for polishing the substrate W.

The CMP head 71 is coupled to a head shaft 78, and the head shaft 78 is coupled to a not-shown head motor. The head motor rotates the CMP head 71 together with the head shaft 78 in a direction indicated by an arrow. The polishing table 73 is coupled to the table motor 76, and the table motor 76 is configured to rotate the polishing table 73 and the polishing pad 72 in a direction indicated by an arrow.

The CMP module 6A is electrically coupled to the operation controller 20 configured to control operations of each component of the CMP module 6A. The CMP head 71, the head motor, and the table motor 76 are electrically coupled to the operation controller 20. Operations of the CMP head 71, the head motor, and the table motor 76 are controlled by the operation controller 20.

CMP processing of the substrate W is performed as follows. The polishing liquid is supplied from the polishing-liquid supply nozzle 75 onto the polishing surface 72a of the polishing pad 72 on the polishing table 73, while the polishing table 73 and the CMP head 71 are rotating in the directions indicated by the arrows in FIG. 8. The substrate W is pressed against the polishing surface 72a of the polishing pad 72 by the CMP head 71 in the presence of the polishing liquid on the polishing pad 72, while the substrate W is being rotated by the CMP head 71. The surface of the substrate W (more specifically, the flat portion P shown in FIGS. 2A and 2B) is polished and planarized by a combination of a chemical action of the polishing liquid and mechanical action(s) of abrasive grains contained in the polishing liquid and/or the polishing pad 72.

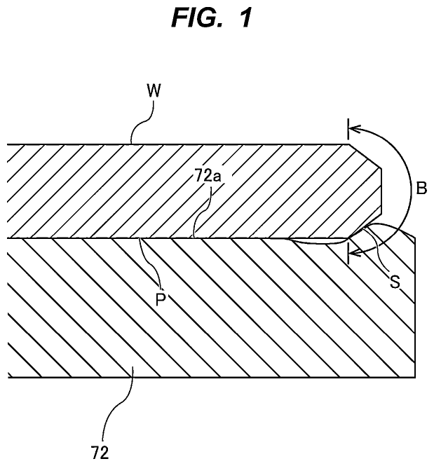

As described with reference to FIG. 1, the inventor of the present invention has found that deformation of the polishing pad 72 when the substrate W is pressed against the polishing pad 72 differs depending on the shape of the bevel portion B of the substrate W. Such a difference in deformation of the polishing pad 72 may cause a variation in a polishing rate of the flat portion P of the substrate W, in particular a polishing rate of the edge portion of the substrate W. According to the embodiment, the bevel portion B of each of the plurality of substrates is polished by the bevel-portion polishing module 4A and/or 4B such that the slope surfaces S of the bevel portions B have the same slope angle α, and CMP processing is sequentially performed on each of the plurality of substrates by the CMP module 6A and/or 6B. Therefore, the same polishing profile can be achieved for the flat portions P of the plurality of substrates (in particular the edge portions of the substrates). In addition, CMP processing can be performed efficiently without adjusting CMP-processing conditions according to the shape of the bevel portion B of each of the substrates.

The substrate W that has been subjected to CMP processing by the CMP module 6A and/or 6B is cleaned and dried by the cleaning-drying section 7 (see FIG. 3). The dried substrate W is transported to the substrate cassette 2 on the load port 10 by the first transfer robot 16.

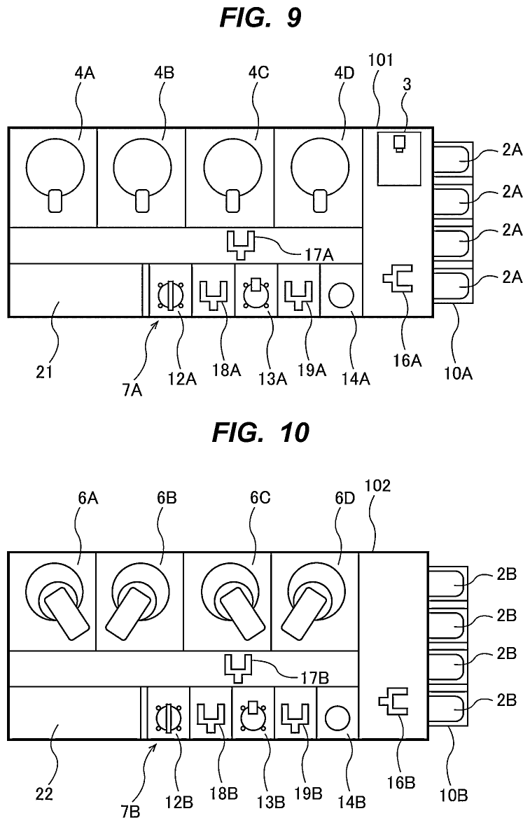

Next, another embodiment of the substrate processing apparatus will be described. In the substrate processing apparatus of this embodiment, the bevel-portion polishing modules are disposed in a first housing 101, and the CMP modules are disposed in a second housing 102. A substrate to be processed is processed in the first housing 101, and is then processed in the second housing 102. FIG. 9 is a plan view showing a configuration of an interior of the first housing 101. As shown in FIG. 9, the substrate processing apparatus includes a bevel-portion-shape measuring module 3, bevel-portion polishing modules 4A to 4D, a cleaning-drying section 7A, a load port 10A, a first transfer robot 16A, a second transfer robot 17A, a third transfer robot 18A, and a fourth transfer robot 19A. The bevel-portion-shape measuring module 3, the bevel-portion polishing modules 4A to 4D, the first transfer robot 16A, the second transfer robot 17A, the third transfer robot 18A, and the fourth transfer robot 19A are arranged in the first housing 101. In one embodiment, the bevel-portion-shape measuring module 3 may be arranged outside the first housing 101.

A plurality of substrates to be processed are housed in a substrate cassette 2A, and the substrate cassette 2A is placed on the load port 10A. The first transfer robot 16A is arranged adjacent to the load port 10A. The first transfer robot 16A removes the substrate to be processed from the substrate cassette 2A on the load port 10A, and transports the substrate to the bevel-portion-shape measuring module 3. The first transfer robot 16A transports the substrate whose shape of the bevel portion has been measured by the bevel-portion-shape measuring module 3 from the bevel-portion-shape measuring module 3 to the second transfer robot 17A. The first transfer robot 16A may remove the substrate to be processed from the substrate cassette 2A on the load port 10A, and may transport the substrate to the second transfer robot 17A without transporting the substrate to the bevel-portion-shape measuring module 3.

In this embodiment, the substrate processing apparatus includes four bevel-portion polishing modules 4A, 4B, 4C, and 4D, while in one embodiment, the substrate processing apparatus may include three or less, or five or more bevel-portion polishing modules.

The bevel-portion polishing modules 4A to 4D are arranged along a longitudinal direction of the first housing 101. The bevel portion of the substrate to be processed is polished by at least one of the bevel-portion polishing modules 4A to 4D. The bevel portion may be polished by only one of the bevel-portion polishing modules 4A to 4D, or the bevel portion may be polished in multiple stages by two or more modules.

The second transfer robot 17A is arranged adjacent to the bevel-portion polishing modules 4A to 4D and the cleaning-drying section 7A. The second transfer robot 17A is configured to receive the substrate from the first transfer robot 16A, and transport the substrate between the bevel-portion polishing modules 4A to 4D. Further, the second transfer robot 17A is configured to transport the substrate received from any one of the bevel-portion polishing modules 4A to 4D to the cleaning-drying section 7A.

The cleaning-drying section 7A includes a first cleaning module 12A and a second cleaning module 13A which are configured to clean the substrate whose bevel portion has been polished by any one of the bevel-portion polishing modules 4A to 4D, and a drying module 14A configured to dry the cleaned substrate. The first cleaning module 12A, the second cleaning module 13A, and the drying module 14A are arranged along the longitudinal direction of the first housing 101.

The third transfer robot 18A is disposed between the first cleaning module 12A and the second cleaning module 13A. The fourth transfer robot 19A is disposed between the second cleaning module 13A and the drying module 14A. The third transfer robot 18A is configured to transport the substrate between the first cleaning module 12A and the second cleaning module 13A. The fourth transfer robot 19A is configured to transport the substrate between the second cleaning module 13A and the drying module 14A.

The substrate processing apparatus further includes an operation controller 21 electrically coupled to the bevel-portion-shape measuring module 3, the bevel-portion polishing modules 4A to 4D, the cleaning-drying section 7A, the first transfer robot 16A, the second transfer robot 17A, the third transfer robot 18A, and the fourth transfer robot 19A. The operation controller 21 is configured to control operations of the bevel-portion-shape measuring module 3, the bevel-portion polishing modules 4A to 4D, the cleaning-drying section 7A, the first transfer robot 16A, the second transfer robot 17A, the third transfer robot 18A, and the fourth transfer robot 19A.

The substrate whose bevel portion has been polished by any one of the bevel-portion polishing modules 4A to 4D in the first housing 101 is cleaned and dried by the cleaning-drying section 7A. Thereafter, the cleaned and dried substrate is subjected to CMP processing in the second housing 102.

FIG. 10 is a plan view showing a configuration of an interior of the second housing 102. As shown in FIG. 10, the substrate processing apparatus includes CMP modules 6A to 6D, a cleaning-drying section 7B, a load port 10B, a first transfer robot 16B, a second transfer robot 17B, a third transfer robot 18B, and a fourth transfer robot 19B. The CMP modules 6A to 6D, the cleaning-drying section 7B, the first transfer robot 16B, the second transfer robot 17B, the third transfer robot 18B, and the fourth transfer robot 19B are arranged in the second housing 102.

The substrates whose bevel portions have been polished, cleaned, and dried in the first housing 101 are housed in a substrate cassette 2B, and the substrate cassette 2B is placed on the load port 10B. The first transfer robot 16B is arranged adjacent to the load port 10B. The first transfer robot 16B removes the substrate whose bevel portion has been polished from the substrate cassette 2B on the load port 10B, and transports the substrate to the second transfer robot 17B.

In this embodiment, the substrate processing apparatus includes four CMP modules 6A, 6B, 6C, and 6D, while in one embodiment, the substrate processing apparatus may include three or less, or five or more CMP modules.

The CMP modules 6A to 6D are arranged along a longitudinal direction of the second housing 102. CMP processing is performed on the flat portion of the substrate by at least one of the CMP modules 6A to 6D. CMP processing of the flat portion may be performed by only one of the CMP modules 6A to 6D, or CMP processing may be performed in multiple stages by two or more modules.

The second transfer robot 17B is arranged adjacent to the CMP modules 6A to 6D, and the cleaning-drying section 7B. The second transfer robot 17B is configured to receive the substrate from the first transfer robot 16B, and transport the substrate between the CMP modules 6A to 6D. Further, the second transfer robot 17B is configured to transport the substrate received from any one of the CMP modules 6A to 6D to the cleaning-drying section 7B.

The cleaning-drying section 7B includes a first cleaning module 12B and a second cleaning module 13B which are configured to clean the substrate whose flat portion has been chemically mechanically polished by any one of the CMP modules 6A to 6D, and a drying module 14B configured to dry the cleaned substrate. The first cleaning module 12B, the second cleaning module 13B, and the drying module 14B are arranged along the longitudinal direction of the second housing 102.

The third transfer robot 18B is disposed between the first cleaning module 12B and the second cleaning module 13B. The fourth transfer robot 19B is disposed between the second cleaning module 13B and the drying module 14B. The third transfer robot 18B is configured to transport the substrate between the first cleaning module 12B and the second cleaning module 13B. The fourth transfer robot 19B is configured to transport the substrate between the second cleaning module 13B and the drying module 14B.

The substrate processing apparatus further includes an operation controller 22 electrically coupled to the CMP modules 6A to 6D, the cleaning-drying section 7B, the first transfer robot 16B, the second transfer robot 17B, the third transfer robot 18B, and the fourth transfer robot 19B. The operation controller 22 is configured to control operations of the CMP modules 6A to 6D, the cleaning-drying section 7B, the first transfer robot 16B, the second transfer robot 17B, the third transfer robot 18B, and the fourth transfer robot 19B.

Details of configurations and operations of the bevel-portion-shape measuring module 3, the bevel-portion polishing modules 4A to 4D, the CMP modules 6A to 6D, the cleaning-drying sections 7A and 7B, and the operation controllers 21 and 22 of this embodiment are the same as the configurations and the operations of the bevel-portion-shape measuring module 3, the bevel-portion polishing modules 4A and 4B, the CMP modules 6A and 6B, the cleaning-drying section 7, and the operation controller 20 of the embodiment described with reference to FIGS. 3 to 8, and duplicated descriptions will be omitted.

According to this embodiment, the bevel portion B of each of the plurality of substrates has been polished by at least one of the bevel-portion polishing modules 4A to 4D in the first housing 101 such that the slope surfaces S of the bevel portions B have the same slope angle α (see FIG. 5) before CMP processing is performed on each of the plurality of substrates by at least one of the CMP modules 6A to 6D in the second housing 102. Therefore, CMP processing can be performed efficiently without adjusting CMP-processing conditions according to the shape of the bevel portion B of each of the substrates.

In the embodiments described with reference to FIGS. 3 to 8 and the embodiments described with reference to FIGS. 9 and 10, the bevel portions B of the plurality of substrates are polished such that the slope surfaces S of the bevel portions B have the same slope angle α, but the present invention is not limited to these embodiments. In one example, the bevel portions B of the plurality of substrates are polished such that the bevel portions B have the same dimension in a radial direction of the substrate, in addition to the same slope angles of the slope surfaces S.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a substrate processing apparatus for processing a substrate, such as a wafer, and more particularly to a substrate processing method and a substrate processing apparatus for polishing a bevel portion of the substrate and performing CMP processing of a flat portion of the substrate.

### REFERENCE SIGNS LIST

2, 2A, 2B substrate cassette
3 bevel-portion-shape measuring module
4A, 4B, 4C, 4D bevel-portion polishing module
6A, 6B, 6C, 6D CMP module
7, 7A, 7B cleaning-drying section
10, 10A, 10B load port
12, 12A, 12B first cleaning module
13, 13A, 13B second cleaning module
14, 14A, 14B drying module
16, 16A, 16B first transfer robot
17, 17A, 17B second transfer robot
18, 18A, 18B third transfer robot
19, 19A, 19B fourth transfer robot
20, 21, 22 operation controller
20a memory
20b arithmetic device
30, 30A, 30B shape measuring device
32 polishing tape
33 polishing head
34 holding stage
35 shaft
37 holding-stage driving mechanism
40 substrate holder
42 lower supply nozzle
43 upper supply nozzle
46 polishing-tape feeding mechanism
47 tape feeding reel
48 tape take-up reel
50, 51, 52, 53 guide roller
54 air cylinder (driving mechanism)
56 tilting mechanism
57 crank arm
58 arm rotating device
68 pressing member
71 CMP head
72 polishing pad
73 polishing table
75 polishing-liquid supply nozzle
76 table motor
78 head shaft
100 housing
101 first housing
102 second housing

1. A substrate processing method of processing a plurality of substrates, comprising:
polishing a bevel portion of each of the plurality of substrates by a polishing tool such that slope surfaces of bevel portions of the plurality of substrates have the same slope angles; and
performing CMP processing of a flat portion of each of the plurality of substrates whose bevel portions have been polished.

2. The substrate processing method according to claim 1, wherein polishing of the bevel portion of each of the plurality of substrates comprises pressing the polishing tool against a slope surface of the bevel portion of each of the plurality of substrates with the same angle of inclination of the polishing tool with respect to the flat portions of the plurality of substrates while each substrate is being rotated.

3. The substrate processing method according to claim 1, further comprising:
measuring a shape of a bevel portion of at least one of the plurality of substrates before polishing of the bevel portions of the plurality of substrates.

4. The substrate processing method according to claim 3, further comprising:
determining a polishing condition for the bevel portions of the plurality of substrates based on a measurement result of the shape of the bevel portion.

5. The substrate processing method according to claim 3, further comprising:
measuring of a shape of a bevel portion of at least one of the plurality of substrates after polishing of the bevel portions of the plurality of substrates; and
polishing the bevel portion of the at least one substrate again when a slope angle of the bevel portion of the at least one substrate has not reached a predetermined angle.

6. The substrate processing method according to claim 1, wherein
a bevel-portion polishing module configured to polish the bevel portions, and a CMP module configured to perform the CMP processing are arranged in the same housing, and
polishing of the bevel portion of each substrate and the CMP processing of each substrate are performed successively.

7. A substrate processing apparatus for processing a plurality of substrates, comprising:
a bevel-portion polishing module configured to press a polishing tool against a bevel portion of each of the plurality of substrates to polish the bevel portion; and
a CMP module configured to perform CMP processing of a flat portion of each of the plurality of substrates whose bevel portions have been polished,
wherein the bevel-portion polishing module is configured to polish the bevel portions of the plurality of substrates such that slope surfaces of the bevel portions of the plurality of substrates have the same slope angles.

8. The substrate processing apparatus according to claim 7, wherein
the bevel-portion polishing module includes a substrate holder configured to hold and rotate each of the plurality of substrates, and
the bevel-portion polishing module is configured to press the polishing tool against a slope surface of the bevel portion of each of the plurality of substrates with the same angle of inclination of the polishing tool with respect to the flat portions of the plurality of substrates while each substrate is being rotated by the substrate holder.

9. The substrate processing apparatus according to claim 7, further comprising:
a bevel-portion-shape measuring module configured to measure a shape of a bevel portion of at least one of the plurality of substrates.

10. The substrate processing apparatus according to claim 9, further comprising:
an operation controller configured to control operations of the bevel-portion-shape measuring module and the bevel-portion polishing module, the operation controller being configured to determine a polishing condition for the bevel portions of the plurality of substrates based on a measurement result of the shape of the bevel portion.

11. The substrate processing apparatus according to claim 9, wherein
the bevel-portion-shape measuring module is configured to measure a shape of a bevel portion of at least one of the plurality of substrates after polishing of the bevel portions of the plurality of substrates, and
the bevel-portion polishing module is configured to polish the bevel portion of the at least one substrate again when a slope angle of the bevel portion of the at least one substrate has not reached a predetermined angle.

12. The substrate processing apparatus according to claim 7, wherein
the bevel-portion polishing module and the CMP module are arranged in the same housing, and
polishing of the bevel portion of each substrate by the bevel-portion polishing module and the CMP processing of each substrate by the CMP module are performed successively.
